(19) United States
(12) Patent Application Publication
(10) Pub. No.: US 2009/0009972 A1
(43) Pub. Date: Jan. 8, 2009

(54) HEAT DISSIPATION MODULE

(75) Inventor: Ching Ho, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AMA PRECISION INC., Taipei (TW)

(21) Appl. No.: 12/164,113

(22) Filed: Jun. 30, 2008

(30) Foreign Application Priority Data
Jul. 2, 2007 (TW) 96124015

(51) Int. Cl. H05K 7/20; H01L 23/34

(52) U.S. Cl. 361/704; 361/710; 257/719

(57) ABSTRACT

A heat dissipation module is disclosed. The heat dissipation module suitable to dissipates heat generating by for a heat source, and multiple fixing parts are disposed around the heat source. The heat dissipation module includes a heat sink, two first rods, and two second rods corresponding to the first rods. The first rods and the second rods are pivotally provided on the heat sink. Each first shaft rod is suitable to rotate about a first axis. Two hooks of each first rod fasten the fixing parts easily. Each second rod is suitable to rotate about a second axis and leans against the heat sink. Thus, each second rod tightly fits with each first rod, and two hooks of each first rod tightly fasten the fixing parts. The heat sink is forced by the first rods, and the heat sink and the heat source abut against each other tightly.

### CROSS-REFERENCE TO RELATED APPLICATION

This application claims the priority benefit of Taiwan application serial no. 96124015, filed on Jul. 2, 2007. The entirety of the above-mentioned patent application is hereby incorporated by reference herein and made a part of specification.

### BACKGROUND OF THE INVENTION

1. Field of the Invention

The invention relates to a heat dissipation module and, more particularly, to a heat dissipation module which utilizes rods to fix a heat sink at a heat source.

2. Description of the Related Art

In recent years, with the rapid development of the science and technology, the operation speed of electronic devices in a computer host is continuously increased, so that the heat generation power of the electronic devices is also increased. To prevent the electronic devices in the computer host from being overheated and losing effectiveness temporarily or permanently, the electronic devices need enough heat dissipation ability to make them work normally.

FIG. 1 is a schematic diagram showing a conventional heat dissipation module assembled on the circuit board, and FIG. 1B is an exploded diagram showing the heat dissipation module and the circuit board shown in FIG. 1A. Please refer to FIG. 1A and FIG. 1B simultaneously. The conventional heat dissipation module 100 includes a heat sink 110 and two clipping rods 120 pivotally provided at the heat sink 110. The chipping rod 120 is a resilient chipping rod, and each clipping rod 120 has two hooks 122. Users can put the heat sink 110 on the heat source 12 of the circuit board 10, and the hooks 122 of each clipping rod 120 fasten the fixing parts 14 around the heat source 12, so that the heat sink 110 can be against the heat source 12 to dissipate the heat for the heat source 12.

In the process of assembling the heat sink 110 on the heat source 12, in the conventional technology, force is applied to the hooks 122 of each clipping rod 120, respectively, to make the clipping rod 120 have temporary resilient deformation, so that a user can make the hooks 122 fasten the corresponding fixing parts 14. However, since the clipping rod 120 has a rod-shaped structure with a less stress area, a user has to use larger force to make the clipping rod 120 have resilient deformation to make each hook 122 clipped with one of a plurality fixing parts 14 around the heat source 12. In other words, the assembly of the heat dissipation module 100 is not convenient.

Since the clipping rod 120 is a resilient clipping rod, when the heat sink 110 is assembled at the heat source 12 via the clipping rod 120, and a reliability test is performed at the heat sink 110 assembled at the heat source 12, the hooks 122 fastening fixing parts 14 get rid of the hold of the fixing parts 14 easily when a vibration occurs, which causes the heat sink 110 to separate from the heat source 12, and then, the heat dissipation module 100 cannot continue to dissipate heat for the heat source 12.

### BRIEF SUMMARY OF THE INVENTION

The invention provides a heat dissipation module which has a preferred assembly convenience and can be assembled on the heat source steadily.

The invention provides a heat dissipation module for dissipating heat generated by a heat source, and a plurality of fixing parts are provided around the heat source. The heat dissipation module includes a heat sink having a plurality of first notches and a plurality of second notches, a plurality of first rods and a plurality of second rods corresponding to the a plurality of first rods. Each of the first rods includes a first pivot part, a plurality of first connecting portions and a plurality of hooks. The first pivot part is pivotally provided at the first notch along a first axis, and the first rod is suitable to rotate about the first axis. A plurality of the first connecting portions are bent from the two ends of the first pivot part, respectively and extend to the outside of the heat sink. Each hook is corresponding to one of the fixing parts, and each hook is bent from the first connecting portions toward the corresponding fixing part and is suitable to fasten thereon.

Each second rod includes a second pivot, a plurality of second connecting portions and a plurality of supporting portions. The second pivot is pivotally provided at the second notch along a second axis, and the second rod is suitable to rotate towards the first rod about the second axis. A plurality of the second connecting portions are bent from the two ends of the second pivot, respectively, and the supporting portion is bent from the corresponding second connecting portion, respectively, and each supporting portion is suitable to be connected with the first connecting portion which extends to the outside of the heat sink. When the hooks fasten the fixing parts, and each supporting portion rotates towards the heat sink about the second axis and leans against the heat sink, each supporting portion tightly fits with the first connecting portion which extends to the outside of the heat sink, so that the hooks of the first rod tightly fasten the fixing parts around the heat source, and the first rod applies an acting force to the heat sink via the corresponding second rod to make the heat sink tightly abut against the heat source.

In one embodiment of the invention, the heat sink includes a base and a fin assembly provided on the base. The first notch is at the connecting area of the fin assembly and the base, and the second notch is at the base and at the two sides of the fin assembly.

In one embodiment of the invention, when each supporting portion tightly fits with the first connecting portion which extends to the outside of the heat sink, the supporting portion leans against the fin assembly.

In one embodiment of the invention, the heat sink is an extrusion heat sink.

In one embodiment of the invention, each second rod further includes a force applying portion provided between the second connecting portions of the second rod.

In one embodiment of the invention, when the hooks fasten the fixing parts, and each supporting portion rotates towards the heat sink about the second axis, the supporting portion is connected to the first connecting portion which extends to the outside of the heat sink first. When the supporting portion continues rotating towards the heat sink and leans against the heat sink, the first connecting portion has resilient deformation and tightly fits with the supporting portion.

In one embodiment of the invention, the extending direction of the supporting portion is parallel to the extending direction of the second pivot.

In one embodiment of the invention, the first connecting portions are preferred to be bent from the two ends of the first pivot part by a 90 degree bending angle.

In one embodiment of the invention, the second connecting portions are preferred to be bent from the two ends of the second pivot by a 90 degree bending angle, and the supporting portion is preferred to be bent inwards from the second connecting portion by a 90 degree bending angle.

In one embodiment of the invention, the distance between a plurality of the second connecting portions of the second rod is larger than the distance between a plurality of first connecting portion of the first rods.

In the invention, the first rods and the second rods corresponding to the first rods are pivotally provided on the heat sink, wherein the first rods can cooperates with the corresponding second rods to provide the heat sink on the heat source easily and steadily. That is, the heat dissipation module of the invention has a preferred assembly convenience. In addition, in the invention, the first rod can fasten the fixing parts around the heat source lastingly and closely via the action of the second rod. Compared with the conventional heat dissipation module which is affected by the external force to separate from the fixing part easily, the heat dissipation module of the invention can be further steadily assembled on the heat source to dissipate the heat for the heat source.

Compared with the conventional technology, the invention has the following advantages.

First, in the invention, each of the hooks of the first rods can tightly fasten the fixing part around the heat source easily only by the rotation of the second rod, and then, the heat sink is assembled on the heat source steadily. Compared with the conventional technology in which force should be applied to the rod with a less stress area to make the hooks of the rod fastening the fixing parts around the heat source, the heat dissipation module of the invention has a preferred assembly convenience.

Second, since the first rod of the invention can maintain a status of resilient deformation lastingly via the action of the second rod and does not be affected by any improper external force easily, when a user performs a reliability test on the heat dissipation module assembled on the heat source, the hooks of the first rod still can tightly fasten the fixing parts around the heat source when they are affected by an external force. Compared with the conventional heat dissipation module which is affected by an external force easily and gets rid of the hold of the fixing parts, the heat dissipation module of the invention can be assembled on the heat source more steadily to dissipate heat for the heat source.

These and other features, aspects, and advantages of the present invention will become better understood with regard to the following description, appended claims, and accompanying drawings.

### BRIEF DESCRIPTION OF THE DRAWINGS

FIG. 1A is a schematic diagram showing a conventional heat dissipation module assembled on a circuit board.

FIG. 1B is an exploded diagram showing the heat dissipation module and the circuit board shown in FIG. 1A.

FIG. 2A is a schematic diagram showing a heat dissipation module assembled on a circuit board according to an embodiment of the invention.

FIG. 2B is an exploded diagram showing the heat dissipation module and the circuit board shown in FIG. 2A.

FIG. 3 is an exploded diagram showing the heat dissipation module shown in FIG. 2A.

FIG. 4A to FIG. 4D are flowcharts showing how to assemble the heat dissipation module of FIG. 2A on the heat source.

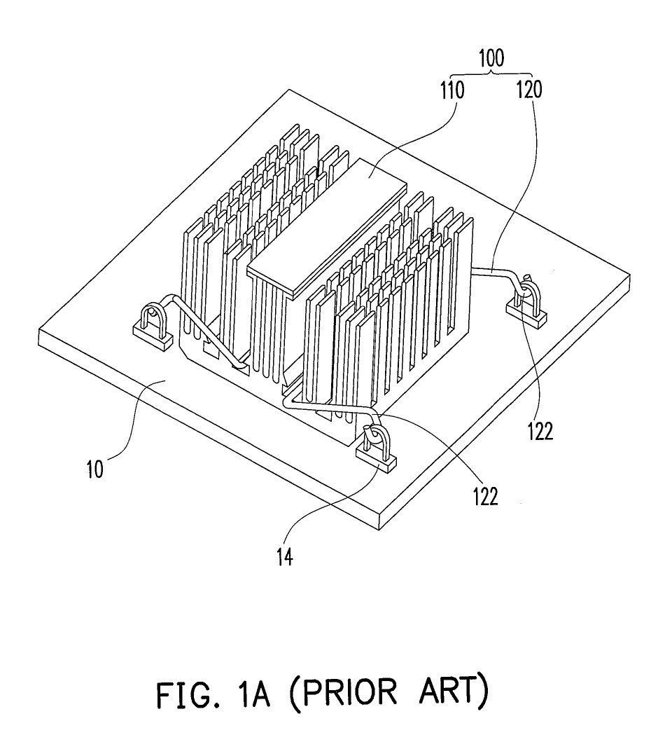

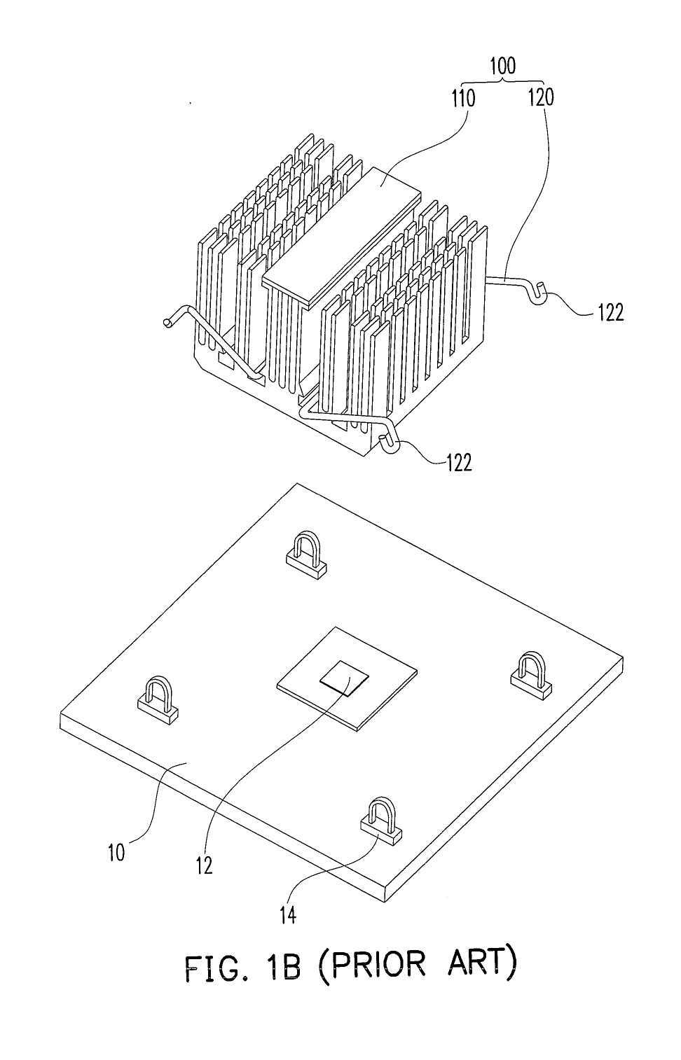

### DETAILED DESCRIPTION OF THE EMBODIMENTS

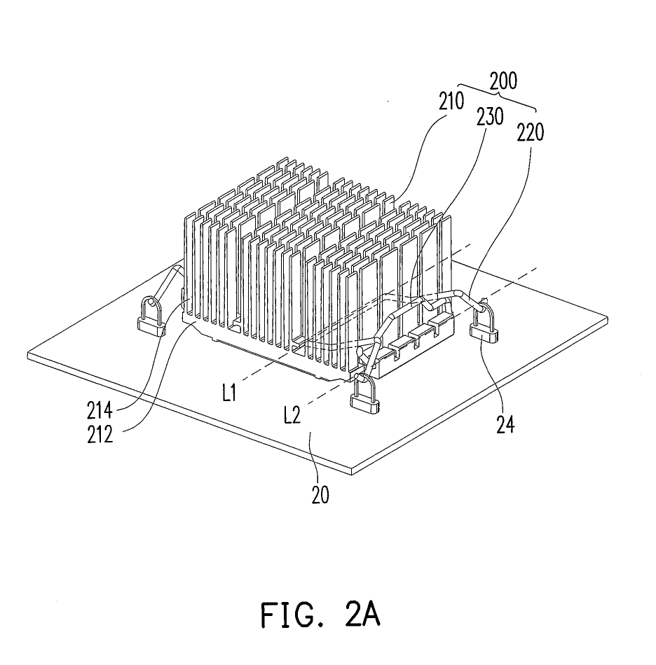

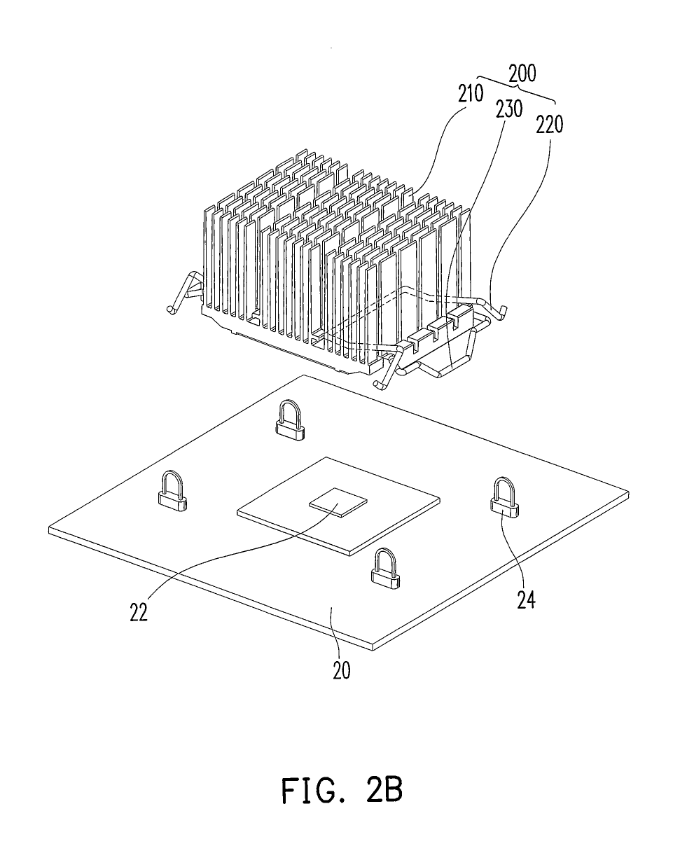

FIG. 2A is a schematic diagram showing a heat dissipation module assembled on a circuit board according to an embodiment of the invention, while the FIG. 2B is an exploded diagram showing the heat dissipation module and the circuit board of the FIG. 2A. Please refer to FIG. 2A and FIG. 2B simultaneously. The heat dissipation module 200 of the embodiment is suitable to be provided at a heat source 22 of a circuit board 20 to dissipate heat generated by the heat source 22, wherein a plurality of fixing parts 24 are provided around the heat source 22 to be clipped with the heat dissipation module 200. The circuit board 20 may be a motherboard. The heat source 22 may be a north bridge chip, a south bridge chip or other heat generating chip on the motherboard.

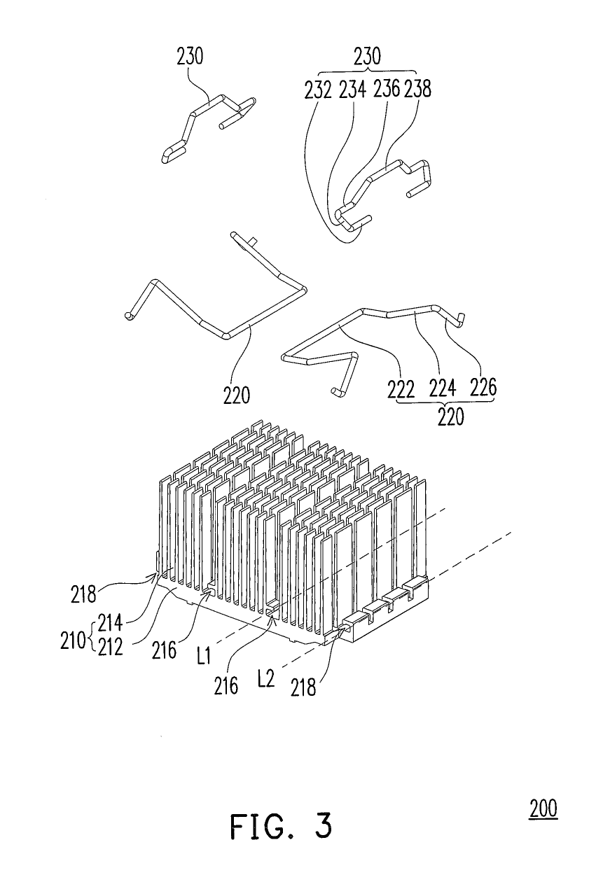

FIG. 3 is an exploded diagram showing a heat dissipation module shown in FIG. 2A. Please refer to FIG. 2A, FIG. 2B and FIG. 3. The heat dissipation module 200 of the embodiment includes a heat sink 210, two first rods 220 and two second rods 230 corresponding to the first rod 220. The heat sink 210 is an extrusion heat sink. The first rods 220 and the second rods 230 are metal rods having the characteristic of resilient deformation, and the first rods 220 can cooperate with the corresponding second rods 230 to make the heat sink 210 provided on the heat source 22 easily and steadily. The structure of the heat dissipation module 200 and how to make the heat dissipation module 200 provided on the circuit board 20 steadily are described in detail in the embodiment hereinbelow.

The structure of the heat dissipation module 200 is described first. Please refer to FIG. 2A and FIG. 3 simultaneously. The heat sink 210 of the embodiment includes a base 212 and a fin assembly 214 provided on the base 212. The heat sink 210 has two first notches 216 and second notches 218. The fin assembly 214 has a plurality of extrusion fins, and the first notches 216 are at the connecting area of the fin assembly 214 and the base 212, while the second notches 218 are on the base 212 and at the two sides of the fin assembly 214.

From the above, in the embodiment, each first rod 220 includes a first pivot part 222, two first connecting portions 224 and two hooks 226. The first pivot part 222 is pivotally provided at the first notch 216 along a first axis L1, and two first connecting portions 224 are bent from the two ends of the first pivot part 222 by a 90 degree bending angle and extend to the outside of the heat sink 210, while each hook 226 is connected to a first connecting portion 224 and bent from the first connecting portion 224 towards the corresponding fixing part 24. In this way, when the heat sink 210 is put on the heat source, the first rod 220 can rotate about the first axis L1, and each hook 226 can fasten the corresponding fixing part 24.

In addition, each second rod 230 includes two second pivots 232, two second connecting portions 234 and two supporting portions 236. The second pivot 232 is pivotally provided at the second notch 218 along a second axis L2, and the two second connecting portions 234 are bent from two ends of each second pivot 232 by a 90 degree bending angle, respectively. Similarly, two supporting portions 236 are bent inward from the two second connecting portions by a 90 degree bending angle, respectively (that is, the extending direction of the supporting portion 236 is parallel to the extending direction of the second pivot 232).

In addition, a force applying portion 238 is provided between the two second connecting portions 234. In this way, users can rotate the second rod 230 via the force applying portion 238 to make the second rod 230 rotate about the second axis L2. The distance between the two second connecting portions 234 of the second rod 230 is larger than the distance between the two first connecting portions 224 of the first rod 220. Therefore, when the second rod 230 rotates toward the first rod 220 about the second axis L2, the supporting portions 236 extending from the second connecting portions 234 can be connected to the first connecting portions 224 which extend to the outside of the heat sink 210.

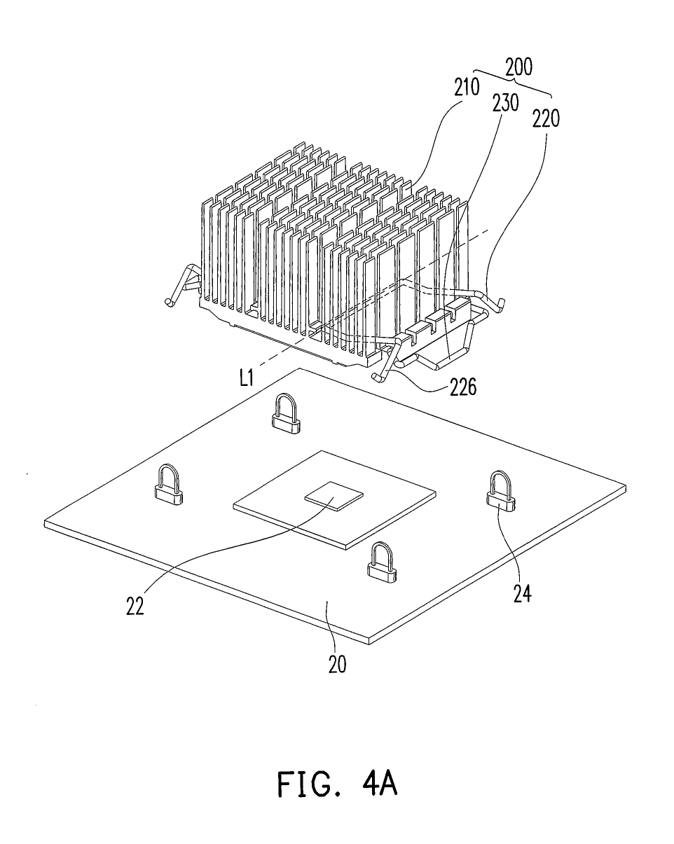

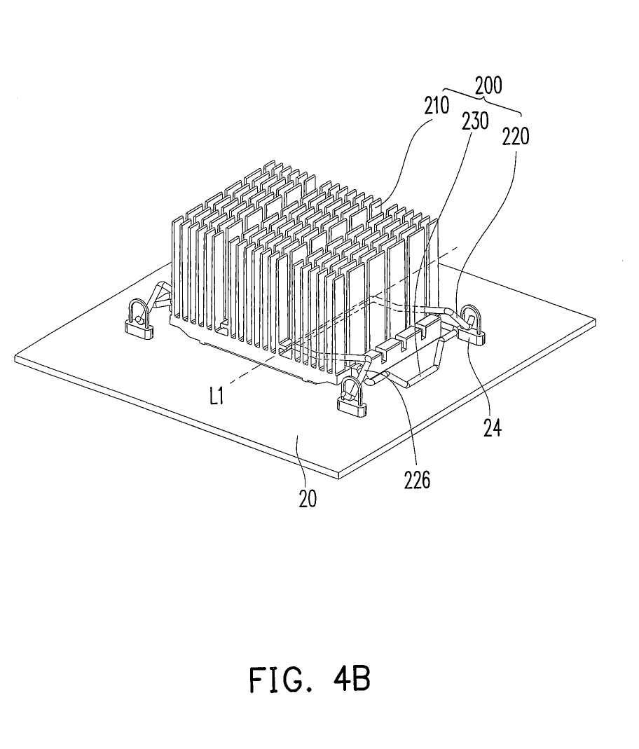

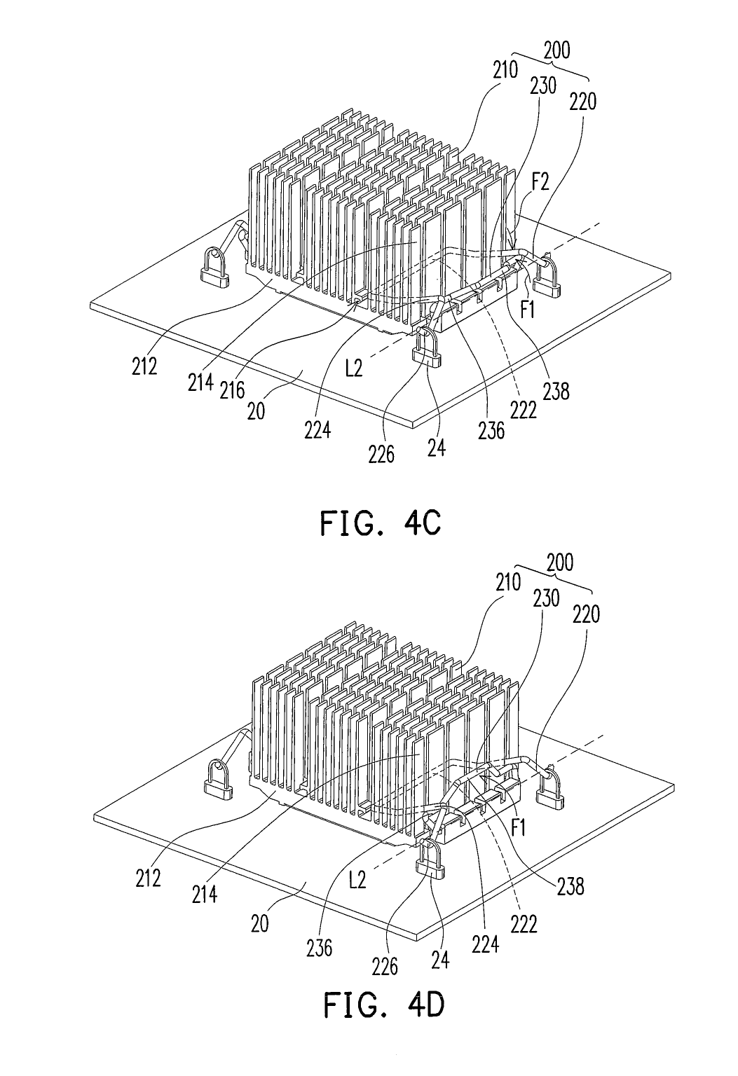

The structure of the heat dissipation module 200 is described hereinbefore. How to assemble the heat dissipation module 200 on the circuit board is described in detail hereinbelow by the flowchart of the assembly in the embodiment. FIG. 4A to FIG. 4D are flowcharts showing how to assemble the heat dissipation module in FIG. 2A on the heat source the circuit board. First, as shown in FIG. 4A to FIG. 4B, the heat dissipation module 200 is put on the heat source 22, and the first rod 220 is rotated about the first axis L1 to make the hooks 226 of each first rod 220 fastened with the corresponding fixing parts 24 (the hooks 236 loosely fit with the fixing parts 24).

As shown in FIG. 4C to FIG. 4D, a rotation force F1 is applied to the force applying portion 238 of each second rod 220, respectively, to make two supporting portions 236 of each second rod 230 rotate toward the heat sink 210 about the second axis L2 and lean against the fin assembly 214 of the heat sink 210. When the supporting portion 236 leans against the fin assembly 214, the supporting portions 236 of each second rod 230 tightly fit with the first connecting portions 224 extending to the outside of the heat sink 210, and then the hooks 226 of the first rod 220 can tightly fasten the fixing parts 24 around the heat source.

Specifically, when the hooks 226 fasten the fixing parts 24, and each supporting portion 236 rotates toward the heat sink 210 about the second axis L2, the supporting portion 236 is connected to the first connecting portion 224 extending to the outside of the heat sink 210 (as shown in FIG. 4C). Since the first pivot part 222 of each first rod 220 is pivotally provided at the first notch 216 of the heat sink 210, and the hooks 226 of each first rod 220 fasten the corresponding fixing parts 24, the two ends of the first connecting portions 224 are fixed. Therefore, when the supporting portions 236 are connected to the first connecting portions 224 extending to the outside of the heat sink 210, the first connecting portions 224 apply an interference force F2 to the supporting portions 236.

In the embodiment, when the rotation force F1 is larger than the interference force F2, the first connecting portions 224 connected to the supporting portions 236 are forced and have resilient deformation, wile the supporting portions 236 can continue to rotate toward the heat sink 210 and lean against the fin assembly 214 (as shown in FIG. 2D) of the heat sink 210. When the supporting portions 236 overcome the interference force F2 and lean against the heat sink 210, the first connecting portions 224 tightly fit with the supporting portions 236, and the second rod 230 against the heat sink 210 can make the first rod 220 keep the state of resilient deformation. In this way, the hooks 226 of the first rod 220 can continuously and tightly fasten the fixing parts 24 around the heat source, while the first rod 220 applies an acting force to the base 212 of the heat sink 210 via the corresponding second rod 230 to make the heat sink 210 tightly abut against the heat source (the heat sink 210 does not have displacement relative to the heat source by the external force easily), and the heat dissipation module 200 can dissipate heat generated by the heat source effectively.

To sum up, in the preferred embodiment of the present invention, two first rods and two second rods corresponding to the first rods are provided on the heat sink. A user can rotate the first rod about the first axis easily to make the hooks of each first rod fasten the fixing parts around the heat source, and a rotation force can be applied to the second rod to make the supporting portions of each second rod rotate toward the heat sink about the second axis and lean against the heat sink. In this way, the supporting portions of the second rod can tightly fit with the first connecting portions extending to the outside of the heat sink, and the hooks of the first rod can tightly fasten the fixing parts around the heat source simultaneously.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A heat dissipation module for dissipating heat generated by a heat source, wherein a plurality of fixing parts are provided around the heat source, the heat dissipation module comprising:
a heat sink having a plurality of first notches and a plurality of second notches, wherein the first notches are between the second notches; and
a plurality of first rods, wherein each of the first rods comprises:
a first pivot part pivotally provided at each of the first notches along a first axis, wherein each of the first rods rotates about the first axis;
a plurality of first connecting portions bent from the two ends of the first pivot part and extending to the outside of the heat sink, respectively;
a plurality of hooks, wherein each of the hooks is corresponding to one of the fixing parts and bent from each of the first connecting portions toward the corresponding each of the fixing parts and fastens each of the fixing parts; and
a plurality of second rods which are corresponding to the first rods, wherein each of the second rods comprises:
a second pivot pivotally provided at each of the second notches along a second axis, wherein each of the second rods is suitable to rotate toward each of the first rods about second axis;
a plurality of second connecting portions bent from the two ends of the second pivot, respectively; and
a plurality of supporting portions bent from each of the second connecting portions, respectively, wherein each of the supporting portions is suitable to be connected to each of the first connecting portions extending to the outside of the heat sink, and
when the hooks fasten the fixing parts, and each of the supporting portions rotates toward the heat sink about the second axis and leans against the heat sink, each of the supporting portions tightly fits with each of the first connecting portions which extends to the outside of the heat sink to make the hooks of each of the first rods tightly fasten the fixing parts provided around the heat source.

2. The heat dissipation module according to claim 1, wherein the heat sink comprises a base and a fin assembly provided on the base, and the first notches are at the connecting area of the fin assembly and the base, while the second notches are provided on the base and at the two sides of the fin assembly.

3. The heat dissipation module according to claim 2, wherein when each of the supporting portions tightly fits with each of the first connecting portions extending to the outside of the heat sink, each of the supporting portions leans against the fin assembly.

4. The heat dissipation module according to claim 1, wherein the heat sink is an extrusion heat sink.

5. The heat dissipation module according to claim 1, wherein each of the second rods further comprises a force applying portion provided between the second connecting portions of each of the second rods.

6. The heat dissipation module according to claim 1, wherein when the hooks fasten the fixing parts, and each of the supporting portions rotates toward the heat sink about the second axis, each of the supporting portions is connected to each of the first connecting portions extending to the outside of the heat sink, and when each of the supporting portions continues rotating toward the heat sink and leans against the heat sink, each of the first connecting portions has resilient deformation and tightly fits with each of the supporting portions.

7. The heat dissipation module according to claim 1, wherein the extending direction of the supporting portion is parallel to the extending direction of the second pivot.

8. The heat dissipation module according to claim 1, wherein the first connecting portions are bent from the two ends of the first pivot part.

9. The heat dissipation module according to claim 1, wherein the second connecting portions are bent from the two ends of the second pivot, respectively, and each of the supporting portions is bent inward from each of the second connecting portions.

10. The heat dissipation module according to claim 1, wherein the distance between the second connecting portions of each of the second rods is larger than the distance between the first connecting portions of each of the first rods.
